(19) United States
(12) Patent Application Publication
(10) Pub. No.: US 2020/0176334 A1
(43) Pub. Date: Jun. 4, 2020

(54) METHOD FOR PROCESSING SEMICONDUCTOR WAFER

(71) Applicant: Shanghai Huali Microelectronics Corporation, Shanghai (CN)

(72) Inventors: Quan JING, Shanghai (CN); Yujie LI, Shanghai (CN)

(21) Appl. No.: 16/662,048

(22) Filed: Oct. 24, 2019

(30) Foreign Application Priority Data
Dec. 4, 2018 (CN) 201811471840.0

(51) Int. Cl. H01L 21/66; H01L 27/146

(52) U.S. Cl. CPC H01L 22/12; H01L 27/14683

(57) ABSTRACT

The disclosure belongs to the field of semiconductor manufacturing, and specifically discloses a method for processing semiconductor wafer. The method comprises: setting process parameters for performing a predetermined semiconductor process; performing the semiconductor process on the semiconductor wafer with the set process parameters; calculating a heat flux value accumulated by the semiconductor process on the semiconductor wafer by using the set process parameter; and determining whether the heat flux value is within a predetermined heat flux value range to determine whether the set process parameters are compliant. The disclosure not only can represent the defects of the device, but also can timely notice the influence of the thermal diffusion effect on the device at a high temperature, thereby more accurately monitoring the stability of the semiconductor process, so as to enhance the accuracy and predictability of the process, and to ensure that the product has stable electrical characteristics and yield.

### CROSS-REFERENCES TO RELATED APPLICATIONS

The present application claims priority to Chinese Patent Application No. 201811471840.0, filed on Dec. 4, 2018, entitled “Method for processing semiconductor wafer”, which is incorporated by reference herein for all purposes.

### FIELD

The disclosure belongs to the field of semiconductor manufacturing, and specifically discloses a method for processing semiconductor wafer.

### BACKGROUND

CMOS image sensor is an electrical solid-state imaging sensor. Due to its high integration, it has superior advantages over traditional CCD in terms of system complexity, reliability, data output, and exposure control accuracy. Due to its small size and light weight, CMOS image sensors are widely used in mobile devices such as smartphones with camera functions.

In the semiconductor process of CMOS image sensors, there is a high demand for the dry degumming process. In the existing high-temperature dry degumming process, the metal ions brought by the front layer process are redistributed under the effect of thermal diffusion, and the CMOS image sensor is very sensitive to the influence of metal ions in the process production. Therefore, the dry degumming processes under different thermal effects will have a significant impact on the pixel performance of CMOS image sensors.

The above problems will also occur in process matching between different equipment suppliers and different types of equipment. The existing evaluation criteria cannot evaluate the influence of metal ions in time during the process development stage. Only in the electrical or yield stage can the differences be found, and different models and structures have different evaluation standards, which cannot be used as the general evaluation standard in the industry.

Studies have shown that the diffusion degree of metal ions in the substrate is proportional to the heat flux. Therefore, in the development and the transfer process, the thermal diffusion effect caused by the dry degumming process has gradually become an important general evaluation standard.

Based on the above reasons, in the development process of the dry-degumming process, a processing method that can not only express the device defects but also timely notice the influence of the thermal diffusion effect on the device at a high temperature is needed, thereby more accurately monitoring the stability of the semiconductor process, so as to enhance the accuracy and predictability of the process, and to ensure that the product has stable electrical characteristics and yield.

### SUMMARY

A brief summary on one or more aspects is given below to provide the basic understanding for these aspects. This summary is not an exhaustive overview of all the contemplated aspects and is neither intended to indicate critical or decisive elements of all aspects nor to attempt to define the scope of any or all aspects. Its sole purpose is to present some concepts of one or more aspects in a simplified form as a preface for a more detailed description presented later.

In order to not only express the device defects but also timely notice the influence of the thermal diffusion effect on the device at a high temperature, thereby more accurately monitoring the stability of the semiconductor process, so as to enhance the accuracy and predictability of the process, and to ensure that the product has stable electrical characteristics and yield, the present disclosure provides a method of processing a semiconductor wafer.

The above method for processing a semiconductor wafer provided by the present disclosure may comprise the steps of:

step 1: setting process parameters for performing a predetermined semiconductor process;

step 2: performing the semiconductor process on the semiconductor wafer with the set process parameters;

step 3: calculating a heat flux value accumulated by the semiconductor process on the semiconductor wafer using the set process parameters; and

step 4: determining whether the heat flux value is within a predetermined heat flux value range to determine whether the set process parameters are compliant.

In one embodiment, in the above method for processing a semiconductor wafer provided by the present disclosure, the semiconductor process comprises a plurality of process steps,

the step 3 comprises calculating a heat flux value accumulated on the semiconductor wafer by each process step;

the step 4 comprises determining whether the heat flux value of each process step is within a predetermined step-corresponding heat flux value range, and determining whether the sum of the heat flux values of the plurality of process steps is within the predetermined heat flux value range to determine whether the set process parameters are compliant.

In one embodiment, in the above method for processing a semiconductor wafer provided by the present disclosure, in the step 4, if the heat flux value of any of the process steps does not meet the predetermined step-corresponding heat flux value range, or the sum of the heat flux values of the plurality of process steps does not meet the predetermined heat flux value range, the set process parameters are not compliant.

In one embodiment, in the above method for processing a semiconductor wafer provided by the present disclosure, the method further comprises:

in response to the set process parameters are not compliant in the step 4, adjusting the process parameters set in step 1 and repeating the steps 2 to 4 until the process parameters are determined compliant in step 4; and

the semiconductor process is performed on a number of semiconductor wafers using the compliant process parameters.

In one embodiment, in the above method for processing a semiconductor wafer provided by the present disclosure, the step 1 comprises setting process parameters for performing the semiconductor process on a first platform and a second platform respectively;

the step 2 comprises performing the semiconductor process on the corresponding semiconductor wafer separately on the first platform and the second platform with the corresponding set process parameters;

the step 3 comprises separately calculating heat flux value accumulated on the corresponding semiconductor wafer on the first platform and the second platform;

the step 4 comprises separately determining whether the heat flux value accumulated on the corresponding semiconductor wafer on the first platform and the second platform is compliant, the method further comprises:

in response to the corresponding process parameters set for the first platform and the second platform are compliant, further determining whether a difference between heat flux values accumulated on the corresponding semiconductor wafers on the first platform and the second platform is less than a predetermined difference threshold to determine whether the semiconductor process of the first platform and the second platform matching.

In one embodiment, in the above method for processing a semiconductor wafer provided by the present disclosure, the semiconductor process comprises a plurality of process steps,

the step 3 comprises separately calculating heat flux value accumulated on corresponding semiconductor wafers on the first platform and the second platform by each process step;

the step 4 comprises separately determining whether the heat flux value of each process step on the first platform and the second platform is within a predetermined step-corresponding heat flux value range, and determining whether the sum of the heat flux values of the plurality of process steps on the first platform and the second platform is within the predetermined heat flux value range to determine whether the set process parameters are compliant;

in response to the corresponding process parameters set for the first platform and the second platform are compliant, the method further comprises:

further determining whether a difference between the heat flux values accumulated on the corresponding semiconductor wafer on the first platform and the second platform is less than a predetermined step-corresponding difference threshold, and determining whether the difference between the sum of the heat flux values of the plurality of process steps on the first platform and the second platform is less than a predetermined difference threshold to determine whether the semiconductor process of the first platform and the second platform matching.

In one embodiment, in the above method for processing a semiconductor wafer provided by the present disclosure, if the heat flux value of any of the process steps does not meet the predetermined step-corresponding heat flux value range, or the sum of the heat flux values of the plurality of process steps does not meet the predetermined heat flux value range, the set process parameters are not compliant; and/or

if the difference between the heat flux values of any of the process steps on the first platform and the second platform does not meet the predetermined step-corresponding difference threshold, or the difference between the sum of the heat flux values of the plurality of process steps does not meet the predetermined difference threshold, then the set process parameters do not match.

In one embodiment, in the above method for processing a semiconductor wafer provided by the present disclosure, further comprising:

if the semiconductor process of the first platform and the second platform do not match, repeating the steps 1 to 3 until it's determined that the semiconductor process of the first platform and the second platform are matching; and

the semiconductor process is performed on a number of semiconductor wafers on the first platform and the second platform using the process parameters that match the semiconductor process of the first platform and the second platform.

In one embodiment, in the above method for processing a semiconductor wafer provided by the present disclosure, the step 3 further comprises:

obtaining a surface temperature change curve of the semiconductor wafer during performing step 2; and

the heat flux value is calculated based on the surface temperature change curve.

In one embodiment, in the above method for processing a semiconductor wafer provided by the present disclosure, the step 3 further comprises:

drawing the surface temperature change curve in a coordinate system in which the time of performing the semiconductor process is the X axis and the surface temperature of the semiconductor wafer is the Y axis; and

the area between the surface temperature change curve and the X-axis is calculated as the heat flux value.

Based on the above description, the beneficial effects of the present disclosure are: can notice the effect of thermal diffusion effect on the pixel performance of CMOS image sensor in time, thereby more accurately monitoring the stability of the semiconductor process, so as to enhance the accuracy and predictability of the process, and to ensure that the product has stable electrical characteristics and yield.

Therefore, according to the above method for processing a semiconductor wafer provided by the present disclosure, the heat flux effect of the above process conditions can be judged in advance, thereby predicting the influence of the heat flux effect on the device earlier, and greatly shortening the evaluation period.

### BRIEF DESCRIPTION OF THE DRAWINGS

The above features and advantages of the present disclosure will be better understood after reading the detailed description of embodiments of the present disclosure combined with the following figures. In the figures, components are not necessarily drawn to scale, and components having similar related features or features may have the same or similar reference signs.

FIG. 1 shows a flow chart of the method for processing a semiconductor wafer according to an embodiment of the present disclosure.

FIG. 2 shows a flow chart of the method for processing a semiconductor wafer according to an embodiment of the present disclosure.

FIG. 3 shows a flow chart of the method for calculating a heat flux value according to an embodiment of the present disclosure.

FIG. 4 shows a schematic diagram of the method for calculating a heat flux value according to an embodiment of the present disclosure.

FIG. 5 shows a flow chart of the method for processing a semiconductor wafer according to an embodiment of the present disclosure.

FIG. 6 shows a comparison view of pixel performance effects on two different models according to an embodiment of the present disclosure.

FIG. 7A shows a schematic diagram of the defect effect exhibited by the method for processing a semiconductor wafer according to an embodiment of the present disclosure.

FIG. 7B shows a schematic diagram of the defect effect exhibited by the method for processing a semiconductor wafer according to an embodiment of the present disclosure.

FIG. 7C shows a schematic diagram of the defect effect exhibited by the method for processing a semiconductor wafer according to an embodiment of the present disclosure.

### REFERENCE SIGNS

H1 initial temperature;

H2 end temperature;

L length of time;

71 pixel performance curve of the first platform;

72 pixel performance curve of the second platform;

73 matching pixel performance curve of the second platform;

101-104 steps of processing a semiconductor wafer method;

201 -207 steps of processing a semiconductor wafer method;

2031-2033 steps of calculating the heat flux value;

601-605 steps of processing a semiconductor wafer method.

### DETAILED DESCRIPTION OF EMBODIMENTS

In some embodiment, the disclosure is described in connection with the embodiments so as to cover other alternatives or modifications that are possible in the embodiments of the disclosure. In order to provide a thorough understanding of the present disclosure, many specific details are included in the following description. The disclosure may also be practiced without these details. In addition, some specific details are omitted in the description in order to avoid confusion or obscuring the present disclosure.

In the description of the present disclosure, it should be noted that the terms “installation”, “connecting”, and “connected” are to be understood broadly, for example, it may be a fixed connection, a detachable connection, or an integral connection; it may be a mechanical connection or an electrical connection; it may be directly connected, or may be indirectly connected through an intermediate medium, and may be internal to both components.

In addition, “upper”, “lower”, “left”, “right”, “top”, “bottom”, “horizontal”, “vertical” as used in the following description shall be taken to mean the orientation as illustrated in the paragraph and the related drawings. This versatile term is used for convenience of description only, and does not represent that the device described is intended to be manufactured or operated in a particular orientation and should not be construed as limiting the disclosure.

It will be understood that the terms “first”, “second”, “third”, etc. may be used to describe various components, regions, layers and/or portions, such components, regions, layers and/or portions should not be limited by these terms, and these terms are used to distinguish different components, regions, layers and/or portions. Thus, a first component, region, layer, and/or portion may be referred to as a second component, region, layer, and/or portion, without departing from some embodiments of the disclosure.

Although the above method is illustrated and described as a series of acts for simplicity of the explanation, it should be understood and appreciated that these methods are not limited by the order of the acts. Some acts may occur in different orders and/or concurrently with other acts from the illustrations and descriptions herein or other acts not illustrated and described herein, in accordance with one or more embodiments.

The existing methods for evaluating the dry gel removal process include:

(1) coating a photo-resist on a silicon wafer, and selecting a main step in the degumming process to match the photo-resist etching rate;

(2) performing process development on the patterned wafer after photolithography, and matching the time used for the over-etched portion in the dry degumming process;

(3) matching the thickness of the oxide film growth on the silicon wafer under different dry degumming processes;

(4) performing process development of the patterned wafer degummed to match the defects, electrical characteristics, and yield after the degumming process.

The above-described scheme using the photo-resist etching rate, the time taken for the over-etched portion, and the oxide film growth thickness as evaluation criteria cannot characterize the influence of the thermal diffusion effect on the metal ions. The time node of the above-mentioned scheme using device defects, electrical characteristics, and yield as evaluation criteria is too late to find problems in the early stage of semiconductor manufacturing process evaluation.

Therefore, the problem of not reflecting the thermal effect data, not directly reflecting the influence of the thermal diffusion effect on the metal ions, the long data validation period, and the lack of principle support exist in the prior art.

In order to not only express the device defects but also timely notice the influence of the thermal diffusion effect on the device at a high temperature, thereby more accurately monitoring the stability of the semiconductor process, so as to make effective evaluation of process matching between production platforms, enhance the accuracy and predictability of the process, and to ensure that the product has stable electrical characteristics and yield, the present disclosure provides an embodiment of a method for processing a semiconductor wafer.

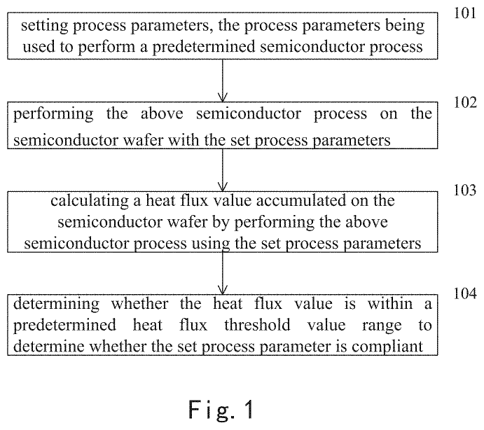

As shown in FIG. 1, the method for processing a semiconductor wafer provided by this embodiment may include the following steps:

101: setting process parameters, the process parameters being used to perform a predetermined semiconductor process;

102: performing the above semiconductor process on the semiconductor wafer with the set process parameters;

103: calculating a heat flux value accumulated on the semiconductor wafer due to the performing of the above semiconductor process using the set process parameters; and

104: determining whether the heat flux value is within a predetermined heat flux threshold value range to determine whether the set process parameter is compliant.

in the above step 101 of the above method for processing a semiconductor wafer provided in this embodiment, the above process parameters for performing a predetermined semiconductor process may include, but are not limited to, power, pressure, substrate temperature, and the ratio of process gases like O₂/N₂/H₂N₂.

In the above method for processing a semiconductor wafer provided in this embodiment, the semiconductor process in the above step 101 may refer to a dry degumming process, and the dry degumming process may be generally divided into a preheating step, a main etching step and an over-etching step. It will be appreciated that in other embodiments, the semiconductor process described above may also include other semiconductor processes that have different effects on the semiconductor device in response to different thermal effects.

In the above method for processing a semiconductor wafer provided in this embodiment, the semiconductor wafer in the above step 102 may be a CMOS image sensor. It will be appreciated that in other embodiments, the semiconductor wafers described above may also include other semiconductor wafers that may be affected significantly in response to different thermal effects.

In the above method for processing a semiconductor wafer provided in this embodiment, the step 103 may be performed to obtain the heat flux value accumulated by the semiconductor wafer to characterize a thermal diffusion effect of the semiconductor wafer. The above heat flux value can be obtained by calculating the integral of the temperature of the semiconductor wafer and the time taken by the semiconductor process, and the calculation formula is as follows:

ϕ=ƒₜ₂^{t1}T×t

Where: ϕ is the heat flux value accumulated by the semiconductor wafer; T is the Celsius temperature of the semiconductor wafer; t is time; t₁ is the initial time of the semiconductor process; t₂ is the termination time of the semiconductor process.

In the above method for processing a semiconductor wafer provided in this embodiment, the heat flux threshold in the above step 104 can be obtained by a large number of experimental statistics. The heat flux threshold above indicates the value of the maximum heat flux that satisfies the semiconductor wafer performance requirements described above.

In some embodiment, the above method for processing a semiconductor wafer provided by the above embodiments provides a method for evaluating a semiconductor process, that is, thermal diffusion effect of metal ions at high temperatures can be evaluated by monitoring the heat flux accumulated on the surface of the wafer, thereby being able to reflect to metal ion contamination of the semiconductor device due to thermal diffusion of metal ions. According to the method provided in the above embodiments, the stability of the semiconductor process can be accurately monitored to enhance the accuracy and predictability of the process deployment, and to ensure stable electrical characteristics and yield of the product.

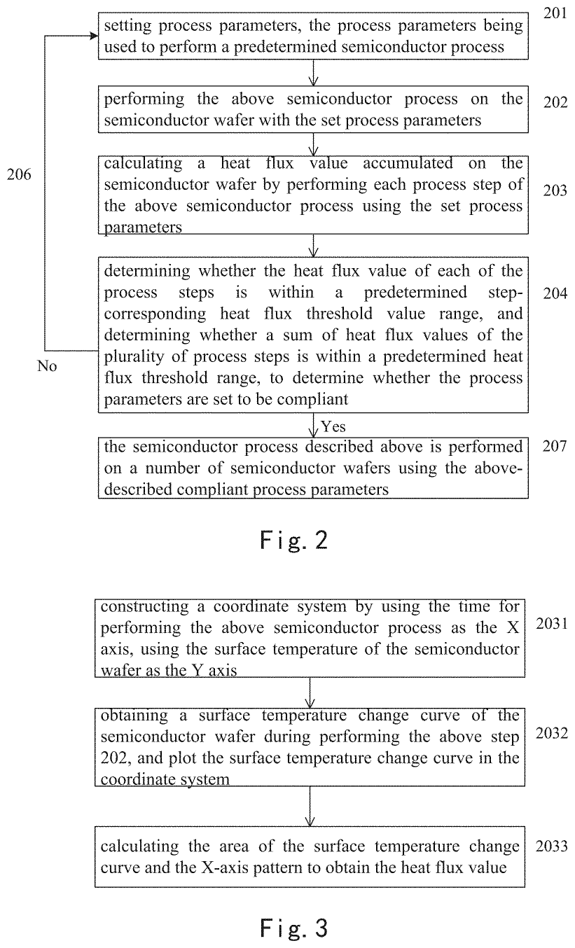

In another embodiment provided by the present disclosure, the process of the method for processing a semiconductor wafer is as shown in FIG. 2, and may include the steps of:

201: setting process parameters, the process parameters being used to perform a predetermined semiconductor process;

202: performing the above semiconductor process on the semiconductor wafer with the set process parameters;

203: calculating a heat flux value accumulated on the semiconductor wafer due to the performing of each process step of the above semiconductor process using the set process parameters;

204: determining whether the heat flux value of each of the process steps is within a predetermined step-corresponding heat flux threshold value range, and determining whether a sum of heat flux values of the plurality of process steps is within a predetermined heat flux threshold range, so as to determine whether the process parameters are set to be compliant;

205: if the heat flux value of any of the process steps does not meet the predetermined step-corresponding heat flux threshold value range, or the sum of the heat flux values of the plurality of process steps does not meet the predetermined heat flux threshold value range, then the determined process parameters are not in compliance;

206: in response to the set process parameters being out of compliance, adjusting the process parameters set in the above step 201, repeating steps 202 to 204, until the process parameters are determined compliant in step 204; and

207: the semiconductor process described above is performed on a number of semiconductor wafers using the above-described compliant process parameters.

In the above method for processing a semiconductor wafer provided in this embodiment, the process steps in the above step 203 refer to the steps of the above semiconductor process. The above process steps may include a preheating step, a main etch step, and an over-etch step. The main etch step may further include a step of etching the shell and a step of etching the photo-resist.

Since the thermal effects of each of the above process steps are different, in order to further improve the calculation accuracy of the above heat flux value, and to facilitate the direct application of the above method for processing a semiconductor wafer, the above step 203 is to separately calculate the heat flux value of the above preheating step, the step of etching the shell, the step of etching the photo-resist and the over-etch step to simplify the calculation method of the heat flux value.

Further, since the heat flux accumulated by each of the above process steps is different on the semiconductor wafer, it is possible to further reflect whether the thermal diffusion effect of the metal ions at a high temperature in each of the process step satisfies the requirement by evaluating whether the heat flux accumulated on the semiconductor wafer for each process step satisfies the requirement. Moreover, the execution of each process step requires setting the process parameters corresponding to the process steps, and by monitoring and evaluating the manner of each process step, the process parameters corresponding to the process steps of the process flow can be adjusted in a targeted manner, so that enabling the process parameters of the corresponding process steps of the process flow compliant.

Moreover, after finding the compliant process parameters, the semiconductor process is performed on the semiconductor platform using the process parameters, so that the heat flux of the semiconductor wafer during processing can meet the expectations. Therefore, the diffusion effect of metal ions of semiconductor wafers at high temperatures is in line with expectations, and the defects caused by metal ion diffusion are controllable, so that the processed semiconductor wafer has good uniformity and good electrical characteristics.

As shown in FIG. 3, it is a flowchart of a preferred method for calculating a heat flux value provided by this embodiment. The above method for calculating the heat flux value may include the steps of:

2031: constructing a coordinate system by using the time for performing the above semiconductor process as the X axis, using the surface temperature of the semiconductor wafer as the Y axis;

2032: obtaining a surface temperature change curve of the semiconductor wafer during performing the above step 202, and plot the surface temperature change curve in the coordinate system;

2033: calculating the area between the surface temperature change curve and the X-axis pattern to obtain the heat flux value.

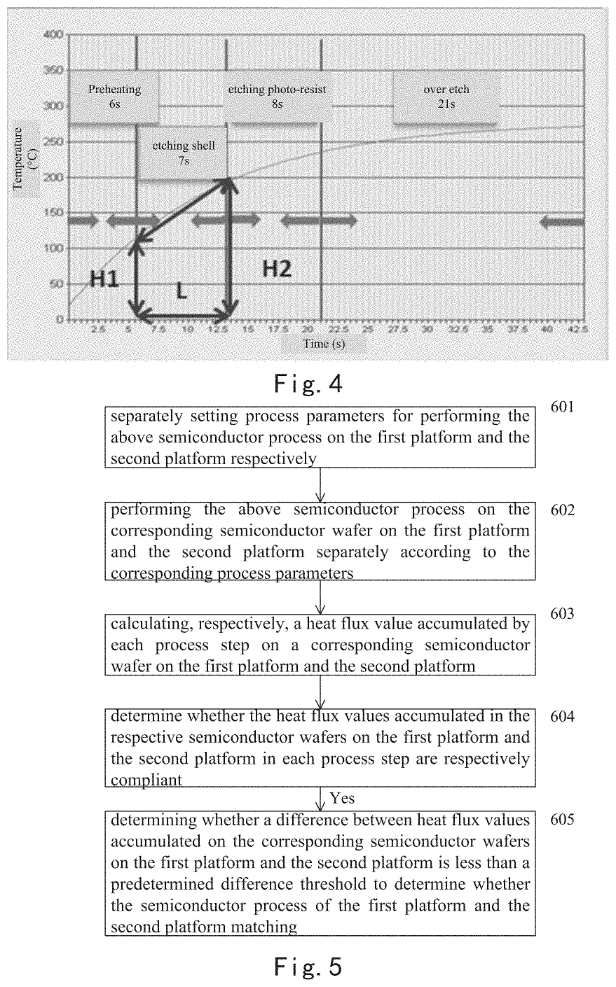

As shown in FIG. 4, according to the above preferred method of calculating the heat flux value, the surface temperature change curve of the semiconductor wafer is divided into four sections corresponding to the preheating step, the etching shell step, the etching photo-resist step, and the over etch step. The area corresponding to each section of the above surface temperature change curve can be approximately equivalent to the area of the trapezoid, and the calculation formula is as follows:

$$S = \frac{L}{2} ( H 1 + H 2 )$$

where: S is the area of the surface temperature change curve in a certain portion; L is the length of time of the portion; H1 is the initial temperature of the portion; H2 is the end temperature of the portion.

The area S of the above surface temperature change curve at each portion indicates the above-described heat flux value ϕ in the corresponding step. The total surface area Sₜₒₜₐₗ of the surface temperature change curve and the X-axis pattern indicates the total heat flux value ϕₜₒₜₐₗ accumulated by the semiconductor process on the semiconductor wafer.

In some embodiments, the foregoing solution for calculating the above heat flux value in each process step is only a preferred solution provided by the embodiment, and is used for improving the calculation accuracy of the heat flux value, and enabling quickly estimate relatively accurate heat flux values.

By comparing the total heat flux value ϕₜₒₜₐₗ obtained by the above preferred embodiment with the heat flux value ϕ obtained by the above integration, it can be found that the heat flux values accumulated by the semiconductor process obtained in the two ways are substantially equal.

It can be understood that the above two schemes for calculating the heat flux value accumulated by the semiconductor process on the semiconductor wafer are only for fully exposing the concept of the present disclosure, and are not intended to limit the present disclosure. In other embodiments, the effect of calculating the above heat flux values based on the same concept and other alternatives.

In the above method for processing a semiconductor wafer provided by the embodiment, the above steps 204-205 may preset a corresponding heat flux threshold corresponding to each of the above process steps, so as to determine whether the set process parameters are compliant or not in the process step.

If the heat flux value of the above process step is within the predetermined step-corresponding heat flux threshold value range, it is determined that the set process parameter is compliant in the process step.

If the heat flux value of the above process step does not meet the predetermined step-corresponding heat flux threshold value range, it is determined that the set process parameter is not compliant in the process step.

The above steps 204-205 may also preset a total heat flux threshold value range corresponding to the entire semiconductor process to determine whether the set process parameters are compliant throughout the semiconductor process.

If the heat flux value of each of the process steps is respectively within the predetermined step-corresponding heat flux value range, and the sum of the heat flux values of the plurality of process steps is within the total heat flux threshold value range, it is then determined that the set process parameters are compliant in the semiconductor process described above.

If the heat flux value of any of the above process steps does not meet the predetermined step-corresponding heat flux threshold value range, although the sum of the heat flux values of the plurality of process steps is within the total heat flux threshold value range, it is determined that the set process parameters are not compliant in the above semiconductor process.

If the sum of the heat flux values of the plurality of process steps does not meet the predetermined heat flux threshold range, it is determined that the set process parameters are completely non-compliant in the semiconductor process described above.

In some embodiments, determining whether the above process parameters are compliant based on the heat flux value of each of the above process steps and the total heat flux value of the entire semiconductor process is only one of preferred solutions of this embodiment.

In other embodiments and the semiconductor wafer has less sensitivity to thermal diffusion effects, if the heat flux value of any of the above process steps does not meet the predetermined step-corresponding heat flux threshold value range, the sum of the heat flux values of the plurality of process steps is within the total heat flux threshold value range, it can also be determined that the set process parameters are compliant in the semiconductor process described above.

In some embodiments, the above method for processing a semiconductor wafer provided by the above embodiments can further enhance the recognition of the influence of the thermal diffusion effect on the pixel performance of the CMOS image sensor at a high temperature, thereby identifying the semiconductor wafer on which the sum of the heat flux of the entire semiconductor process is compliant, but the heat flux of any one of the process steps is not compliant. By performing the above-described semiconductor process on a plurality of semiconductor wafers using the above-described compliant process parameters, a semiconductor wafer having a heat flux compliant for each process step can be obtained.

In another embodiment provided by the present disclosure, the process of the method for processing a semiconductor wafer is as shown in FIG. 5, and may include the steps of:

601: setting process parameters for performing the above semiconductor process on the first platform and the second platform respectively;

602: performing the above semiconductor process on the corresponding semiconductor wafer on the first platform and the second platform respectively according to the corresponding process parameters;

603: calculating, respectively, a heat flux value accumulated by each process step on the corresponding semiconductor wafer on the first platform and the second platform;

604: determine whether the heat flux value accumulated in the respective semiconductor wafer on the first platform and the second platform in each process step are respectively compliant;

605: in response to the corresponding process parameters set for the first platform and the second platform are compliant, further determining whether a difference between heat flux values accumulated on the corresponding semiconductor wafer on the first platform and the second platform is less than a predetermined difference threshold to determine whether the semiconductor process of the first platform and the second platform are matching.

In the above method for processing a semiconductor wafer provided by the embodiment, under the premise that the process parameters of the semiconductor process are compliant, it can be judged whether the above semiconductor processes on two platforms of different models match or not by comparing whether the heat flux value of each of the above process steps is within a difference threshold of a preset corresponding step, and/or whether the total heat flux value of the entire semiconductor process is within a preset difference threshold.

If the difference between the heat flux values accumulated on the corresponding semiconductor wafers on the first platform and the second platform is less than a predetermined step-corresponding difference threshold, it is determined that the set process parameters for the process steps of the first platform and the second platform match.

The above matched process parameters enable superior uniformity between semiconductor wafers processed by different machines.

If the difference between the heat flux values accumulated on the corresponding semiconductor wafers on the first platform and the second platform does not meet the predetermined step-corresponding difference threshold, it is determined that the set process parameters for the process steps of the first platform and the second platform do not match.

Further, if the difference between the heat flux values accumulated on the corresponding semiconductor wafers on the first platform and the second platform in each of the above process steps is less than a predetermined step-corresponding difference threshold, and the difference between the sum of the heat flux values of the plurality of process steps on the first platform and the second platform is less than a predetermined difference threshold, it is determined that the set process parameters for the above semiconductor process of the first platform and the second platform match.

Further, the process parameters matched for each process step can enable superior uniformity between semiconductor wafers processed by different machines.

If the difference between the heat flux values accumulated on the corresponding semiconductor wafers on the first platform and the second platform in any of the above process steps does not meet the predetermined step-corresponding difference threshold, or the difference between the sum of the heat flux values of the plurality of process steps on the first platform and the second platform does not meet the predetermined difference threshold, it is determined that the set process parameters for the above semiconductor process of the first platform and the second platform do not match.

In some embodiments, the solution of determining whether the set process parameters for the above semiconductor process of the first platform and the second platform match based on the heat flux value for each of the above process steps, and on the total heat flux value for the entire semiconductor process described above is only a preferred solution of the embodiment. In other embodiments of the above semiconductor wafers that are less sensitive to thermal diffusion effects, if the heat flux value of any of the above process steps does not meet the heat flux threshold value range of the predetermined corresponding step, and the sum of the heat flux values of the plurality of process steps is within a predetermined total heat flux threshold value range, it is also possible to determine that the set process parameters for the above semiconductor process of the first platform and the second platform match.

As shown in Table 1, through the calculation and determination using the method for processing a semiconductor wafer provided by the embodiment, the heat flux values of the preheating step, the heat flux values of the degumming step and the total heat flux values of the above semiconductor process of the first platform (model 1) and the second platform (model 2) can be respectively obtained. The degumming step includes the step of etching the shell, the step of etching the photo-resist, and the step of over-etching.

TABLE 1

| | Heat flux | | |
|---|---|---|---|
| | area of | area of | Total |
| Comparison | preheating step | degumming step | area |
| model 1 | 280 | 6120 | 6400 |
| model 2 | 1000 | 7650 | 8650 |
| model 2′ | 100 | 6400 | 6500 |

By comparing the two sets of data of the first platform (model 1) and the second platform (model 2), there is a large difference in the heat flux value of the preheating step, the heat flux value of the degumming step, and the total heat flux values of the process.

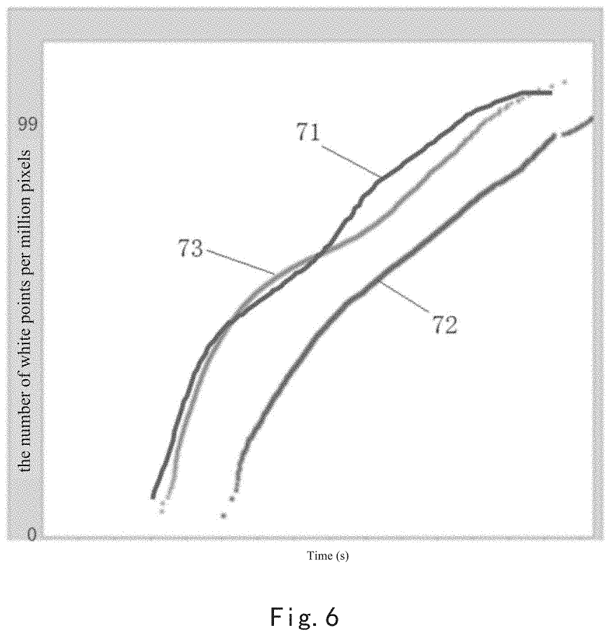

Correspondingly, as shown in FIG. 6, it is a comparison diagram of pixel performance effects on the above two different platforms (model 1 and model 2) provided by this embodiment.

It can be seen from the figure that both the heat flux value of each of the above process steps and the total heat flux value of the semiconductor process on the first platform are smaller than that on the second platform, the pixel performance effect curve 71 of the first platform is significantly higher than the pixel performance curve 72 of the second platform. Therefore, the process parameters of the first platform (model 1) and the second platform (model 2) do not match.

Since the heat flux value on one platform is in one-to-one correspondence with the process parameters on the platform, in order to match the process parameters of the first platform and the second platform, the following steps can be further performed in this embodiment:

606: if the semiconductor process of the first platform and the second platform does not match, repeat step 601 to step 603 until it is determined that the set process parameters for the above semiconductor process of the first platform and the second platform matching;

607: performing the semiconductor process on a plurality of semiconductor wafers on the first platform and the second platform by using process parameters that enabling the semiconductor process of the first platform and the second platform matching.

Through the matching of the above steps 606-607, the heat flux value of each of the above process steps of the matched second platform, the total heat flux value of the semiconductor process, and the pixel performance curve 73 of the matched second platform can be obtained.

From the data in Table 1, it can be found that the matched second platform (model 2′) has the heat flux values of the respective process steps and the total heat flux value of the semiconductor process described above similar to those of the first platform.

Correspondingly, the pixel performance curve 73 of the matched second platform also exhibits a feature similar to the pixel performance effect curve 71 of the first platform.

Therefore, after the processing of the preferred solution of the method for processing a semiconductor wafer provided by the embodiment, not only the compliant process parameters of the first platform and the second platform of different models can be obtained, the preferred process parameters that enabling the first platform and the second platform matching to each other can also be obtained.

Further, after finding the compliant and matched process parameters on the plurality of machines, using the process parameters to execute the semiconductor process on the corresponding semiconductor machine enables different machines to process the semiconductor wafer of which the accumulated heat fluxes are in line with expectations, so that the diffusion effect of metal ions of semiconductor wafers at high temperatures is in line with expectations, and defects caused by diffusion of metal ions are controllable. At the same time, the matched process parameters make the semiconductor wafer processed by different machines have better consistency and good electrical characteristics.

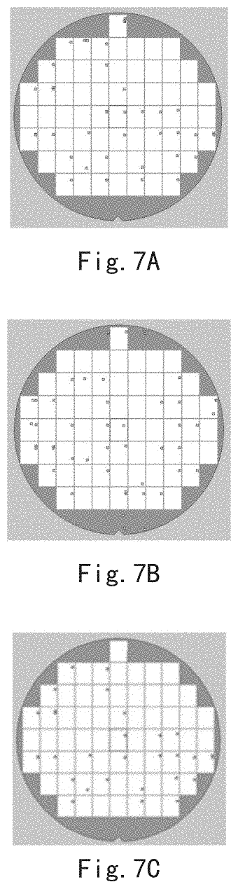

In order to verify whether the above method for processing a semiconductor wafer provided by the embodiment can obtain the same defect performance effect by matching the above process parameters, also provided herein is a schematic illustration of the deficiencies exhibited by the above described method of processing a semiconductor wafer as illustrated in FIGS. 7A-7C.

As shown in FIG. 7A, it is a schematic diagram showing the defect effect exhibited by the above-described model 1.

As shown in FIG. 7B, it is a schematic diagram showing the defect effect exhibited by the above-described model 2.

As shown in FIG. 7C, it is a schematic view of the defect effect exhibited by the above model 2′.

As can be seen from FIGS. 7A-7C, the above-described method of processing a semiconductor wafer has a large difference in the defect effect exhibited by the model 1 in which the process parameters are not matched and the model 2. By using the above-described method of processing a semiconductor wafer provided in the present embodiment, it is possible to obtain almost the same defect performance effect on the above-described model 1 and the above-described model 2′ by matching the above-described process parameters.

Combined with the heat flux values in Table 1, the FIGS. 6 and 7, it is also possible to counteract the non-negligible effect of thermal diffusion on the pixel performance of CMOS image sensors.

Based on the above description, the above method for processing a semiconductor wafer proposed by the present disclosure can calculate the difference in accumulated heat flux of the semiconductor wafer during the above semiconductor process under different conditions by simulating a semiconductor wafer surface temperature variation curve of the semiconductor process. Thereby more accurately monitoring the stability of the semiconductor process, so as to enhance the accuracy and predictability of the process, and to ensure that the product has stable electrical characteristics and yield.

The above method for processing a semiconductor wafer proposed by the present disclosure is particularly effective for a product sensitive to metal ion contamination such as a CMOS image sensor, and has a more prominent application requirement for evaluation of a dry degumming process.

What is claimed is:

1. A method of processing a semiconductor wafer, comprising:
step 1: setting process parameters for performing a predetermined semiconductor process;
step 2: performing the semiconductor process on the semiconductor wafer with the set process parameters;
step 3: calculating a heat flux value accumulated by the semiconductor process on the semiconductor wafer using the set process parameters; and
step 4: determining whether the heat flux value is within a predetermined heat flux value range to determine whether the set process parameters are compliant.

2. The method of claim 1, wherein the semiconductor process comprises a plurality of process steps,
the step 3 comprises calculating a heat flux value accumulated on the semiconductor wafer by each process step;
the step 4 comprises determining whether the heat flux value of each process step is within a predetermined step-corresponding heat flux value range, and determining whether the sum of the heat flux values of the plurality of process steps is within the predetermined heat flux value range to determine whether the set process parameters are compliant.

3. The method of claim 2, wherein in the step 4, if the heat flux value of any of the process steps does not meet the predetermined step-corresponding heat flux value range, or the sum of the heat flux values of the plurality of process steps does not meet the predetermined heat flux value range, the set process parameters are not compliant.

4. The method of claim 1, wherein the method further comprises:
in response to the set process parameters are not compliant in the step 4, adjusting the process parameters set in step 1 and repeating the steps 2 to 4 until the process parameters are determined compliant in step 4; and
the semiconductor process is performed on a number of semiconductor wafers using the compliant process parameters.

5. The method of claim 1, wherein the step 1 comprises setting process parameters for performing the semiconductor process on a first platform and a second platform respectively;
the step 2 comprises performing the semiconductor process on the corresponding semiconductor wafer separately on the first platform and the second platform with the corresponding set process parameters;
the step 3 comprises separately calculating heat flux value accumulated on the corresponding semiconductor wafer on the first platform and the second platform;
the step 4 comprises separately determining whether the heat flux value accumulated on the corresponding semiconductor wafer on the first platform and the second platform is compliant, the method further comprises:
in response to the corresponding process parameters set for the first platform and the second platform are compliant, further determining whether a difference between heat flux values accumulated on the corresponding semiconductor wafer on the first platform and the second platform is less than a predetermined difference threshold to determine whether the semiconductor process of the first platform and the second platform matching.

6. The method of claim 5, wherein the semiconductor process comprises a plurality of process steps,
the step 3 comprises separately calculating heat flux value accumulated on corresponding semiconductor wafer on the first platform and the second platform by each process step;
the step 4 comprises separately determining whether the heat flux value of each process step on the first platform and the second platform is within a predetermined step-corresponding heat flux value range, and determining whether the sum of the heat flux values of the plurality of process steps on the first platform and the second platform is within the predetermined heat flux value range to determine whether the set process parameters are compliant;
in response to the corresponding process parameters set for the first platform and the second platform are compliant, the method further comprises:
further determining whether a difference between the heat flux values accumulated on the corresponding semiconductor wafer on the first platform and the second platform is less than a predetermined step-corresponding difference threshold, and determining whether the difference between the sum of the heat flux values of the plurality of process steps on the first platform and the second platform is less than a predetermined difference threshold to determine whether the semiconductor process of the first platform and the second platform matching.

7. The method of claim 6, wherein if the heat flux value of any of the process steps does not meet the predetermined step-corresponding heat flux value range, or the sum of the heat flux values of the plurality of process steps does not meet the predetermined heat flux value range, the set process parameters are not compliant; and/or
if the difference between the heat flux values of any of the process steps on the first platform and the second platform does not meet the predetermined step-corresponding difference threshold, or the difference between the sum of the heat flux values of the plurality of process steps does not meet the predetermined difference threshold, then the set process parameters do not match.

8. The method of claim 6, further comprising:
if the semiconductor process of the first platform and the second platform do not match, repeating the steps 1 to 3 until it's determined that the semiconductor process of the first platform and the second platform are matching; and
the semiconductor process is performed on a number of semiconductor wafers on the first platform and the second platform using the process parameters that match the semiconductor process of the first platform and the second platform.

9. The method of claim 1 wherein the step 3 further comprises:
obtaining a surface temperature change curve of the semiconductor wafer during performing step 2; and
the heat flux value is calculated based on the surface temperature change curve.

10. The method of claim 9 wherein the step 3 further comprises:
drawing the surface temperature change curve in a coordinate system in which the time of performing the semiconductor process is the X axis and the surface temperature of the semiconductor wafer is the Y axis; and
the area between the surface temperature change curve and the X-axis is calculated as the heat flux value.
